(19) United States
(12) Patent Application Publication
(10) Pub. No.: US 2014/0070235 A1
(43) Pub. Date: Mar. 13, 2014

(54) WIRE BONDS AND LIGHT EMITTER DEVICES AND RELATED METHODS

(71) Applicants: Peter Scott Andrews, Durham, NC (US); Erin Welch, Chapel Hill, NC (US); Andrew Signor, (US); Christopher P. Hussell, Cary, NC (US)

(72) Inventors: Peter Scott Andrews, Durham, NC (US); Erin Welch, Chapel Hill, NC (US); Andrew Signor, (US); Christopher P. Hussell, Cary, NC (US)

(21) Appl. No.: 13/607,217

(22) Filed: Sep. 7, 2012

(51) Int. Cl. H01L 33/48

(52) U.S. Cl. CPC H01L 33/48
USPC 257/88; 438/28

(57) ABSTRACT

Improved wire bonds and light emitting devices and related methods are disclosed. In one aspect, an improved wire bond can include a shaped wire bond, where at least a portion of the wire bond includes a negative kink and/or a concave shape with respect to an underlying substrate.

### TECHNICAL FIELD

The subject matter disclosed herein relates generally to wire bonds, and more particularly to improved wire bonds and light emitting devices and related methods for forming wire bonds, particularly for use with light emitting diode (LED) devices.

### BACKGROUND

A material's coefficient of thermal expansion (CTE) describes a number or percentage relating to how much the material expands or contracts when heated or cooled. For example, CTE can numerically represent the tendency of a material to change in volume in response to a change in temperature. Some materials can change negatively (e.g., shrink) when experiencing a rise in temperature. Most materials, however, expand by a small percentage as they heat up. CTE can be expressed in parts per million per degree Celsius (ppm/° C.).

Printed circuit boards (PCBs), metal core printed circuit boards (MCPCBs), flexible circuits or circuitry, FR-4 laminates, and/or other substrates are commonly used either in conjunction with and/or within portions of light emitter devices, such as components, packages, products, and/or fixtures incorporating light emitting diodes (LEDs or LED chips). In general, such substrates and/or light emitter devices can incorporate different materials and/or layers including metals, polymers, silicones, and/or ceramic materials which can expand in length and/or width by different amounts upon heating during elevated operating temperatures. PCBs can, for example, expand in length and/or width by approximately 14 ppm/° C., and silicones can, for example, expand in length and/or width by as much as approximately 40 ppm/° C. or more or 55 ppm/° C. or more. In some aspects, silicones can expand in length by approximately 250 ppm/° C., approximately 270 ppm/° C., or approximately 300 ppm/° C. or more. The mismatch in CTEs between different materials can cause problems within light emitter devices, including LED packages, components, or fixtures. In some aspects, CTE differences can be approximately 5 ppm/° C. or more and can correspond in differences in expansion of different materials by approximately 10 μm to more than 50 μm within a given light emitter device or package. This difference in growth of materials within a given device or package can attribute to strained and/or broken wire bonds.

A significant failure rate of LED chips within light emitter devices or packages has further been attributed to joining LED chips with materials having different CTEs while being encapsulated in a silicone matrix. The mismatch in CTEs of the different materials can cause wire bonds which interconnect the LED chips to electrical components within a light emitter to fail, typically proximate the neck or stitch of the wire bond. The mismatch in CTEs can further increase the amount of long term strain or motions and stresses applied to a wire bond during thermal cycling which occurs during operating conditions, thus, CTE mismatch can ultimately attribute to failure of the wire bond, and therefore, failure of the LED chip and/or light emitter component.

Conventional methods of addressing CTE mismatch within integrated circuit devices, which may be applied to light emitter devices, include using low CTE materials, such as substrates having cores of copper-invar-copper (CIC) and copper-molybdenum-copper (CMC) materials having CTEs of approximately 8 ppm/C and 6 ppm/C, respectively. However, low CTE materials are becoming more specialized and more expensive to incorporate into larger, more innovative lamp designs. In addition, high CTE materials such as silicones may be desired to focus light or improve optical properties of light emitter devices. Such mismatched material systems can, therefore, put additional requirements upon wire bonds.

Thus, a need for more robust wire bonds and/or wire bond shaping is needed to improve reliability and prevent failure of LED chips within light emitter devices. A need for more robust wire bonds and/or wire bond shaping for thermal compensation is also needed to prevent failure of LED chips within silicone encapsulated light emitter devices. Wire bonds and wire bond shaping as described herein allows for reduced stresses and temperature compensating in the wire eliminating wire failures associated with thermal cycling and operating conditions.

### SUMMARY

In accordance with this disclosure, wire bonds, and more particularly improved wire bonds and related methods for forming wire bonds, particularly for use with light emitting diode (LED) devices are provided and described herein. Wire bonds and wire bond shaping as described herein can minimize and prevent wire failures and improve reliability of light emitter chips and/or devices, in part by alleviating the motions, stresses, and/or strains associated with thermal cycling, movement, or vibration during operating conditions. In one aspect, an improved wire bond can include a shaped wire bond, where at least a portion of the wire bond is shaped to include a negative kink and/or a concave shape with respect to an underlying substrate. Shaping the wire bond can comprise forming the wire bond to have at least one concave portion to allow the wire bond to elongate when necessary to relieve stresses associated with hot and/or cold temperatures and/or mismatches in coefficient of thermal expansion (CTE) for various materials within a light emitter device or package. It is, therefore, an object of the present disclosure to provide improved wire bonds and related methods of forming improved wire bonds for producing more reliable light emitting diode (LED) chips, devices, packages, and/or components.

These and other objects of the present disclosure as can become apparent from the disclosure herein are achieved, at least in whole or in part, by the subject matter disclosed herein.

### BRIEF DESCRIPTION OF THE DRAWINGS

A full and enabling disclosure of the present subject matter including the best mode thereof to one of ordinary skill in the art is set forth more particularly in the remainder of the specification, including reference to the accompanying figures, in which:

FIGS. 1A and 1B of the drawings are elevational side views illustrating examples of wire bonds and wire bonding according to the disclosure herein;

FIGS. 2A through 2D of the drawings illustrate examples of steps that can occur in wire bond formation according to the disclosure herein;

FIGS. 2E and 2F of the drawings are SEM micrograph images of examples of ball bonding and wedge bonding wire bonds, respectively, according to the disclosure herein;

FIGS. 3 through 8 of the drawings are various views illustrating examples of wire bonds and wire bonding within light emitter devices or packages and/or in association with light emitting diode (LED chips) according to the disclosure herein;

FIGS. 9A and 9B of the drawings are elevational side views illustrating wire bonds and wire bonding within light emitter devices or packages according to the disclosure herein; and

FIG. 10 is a cross-sectional view illustrating examples of wire bonds and wire bonding within a light emitter device or package and/or in association with LED chips according to the disclosure herein.

### DETAILED DESCRIPTION

The subject matter disclosed herein is directed to wire bonds and light emitter devices and related methods for forming wire bonds, particularly for use with light emitting diode (LED) devices. Wire bond and wire bond shaping as disclosed herein can be used with devices, packages, components, products and/or fixtures which incorporate light emitters, such as light emitting diodes (LEDs or LED chips). Wire bonds and wire bond shaping as described herein can minimize and prevent wire failures and improve reliability of light emitters, in part by alleviating the motions, stresses, and/or strains associated with thermal cycling, movement, or vibration during operating conditions. In some aspects, portions of novel wire bonds disclosed herein can move and/or elongate to alleviate strains associated with materials having different (or mismatched) coefficients of thermal expansion (CTEs) within one light emitter device, package, component, or fixture.

Wire bonds and wire bond shaping as described herein is not limited to any specific lighting device, fixture, component, package, and/or chip component. Thus, wire bonds and wire bond shaping as disclosed herein can be used in association with any type or design of light emitter device, package, fixture, product, and/or component (e.g., including packaged, unpackaged, ceramic based devices, and/or chip-on-board (COB) components) and with any type of LED chip which is capable of being wire bonded (e.g., a horizontally or vertically structured LED chip, flip-chip, ESD protection devices, Zener diode, silicon based chips, silicon carbide (SIC) based chips, sapphire based chips, or chips with or without growth and/or carrier substrates). Wire bonds and wire bonding processes disclosed herein can be formed via manual processes, automatic processes, and/or combinations thereof. Wire bonds can be shaped during formation or application of the wire bonds within the light emitter device using the wire bonding tool, or wire bonds can be shaped after formation of each wire bond via depression of a wire bond using any suitable tool.

As illustrated in the various figures, some sizes of structures or portions are exaggerated relative to other structures or portions for illustrative purposes and, thus, are provided to illustrate the general structures of the present subject matter. Furthermore, various aspects of the present subject matter are described with reference to a structure or a portion being formed on other structures, portions, or both. As will be appreciated by those of skill in the art, references to a structure being formed “on” or “above” another structure or portion contemplates that additional structure, portion, or both may intervene. References to a structure or a portion being formed “on” another structure or portion without an intervening structure or portion are described herein as being formed “directly on” the structure or portion. Similarly, it will be understood that when an element is referred to as being “connected”, “attached”, or “coupled” to another element, it can be directly connected, attached, or coupled to the other element, or intervening elements may be present. In contrast, when an element is referred to as being “directly connected”, “directly attached”, or “directly coupled” to another element, no intervening elements are present.

Furthermore, relative terms such as “on”, “above”, “upper”, “top”, “lower”, or “bottom” are used herein to describe one structure's or portion's relationship to another structure or portion as illustrated in the figures. It will be understood that relative terms such as “on”, “above”, “upper”, “top”, “lower” or “bottom” are intended to encompass different orientations of the package or component in addition to the orientation depicted in the figures. For example, if the package or component in the figures is turned over, structure or portion described as “above” other structures or portions would now be oriented “below” the other structures or portions. Likewise, if the package or component in the figures are rotated along an axis, structure or portion described as “above”, other structures or portions would be oriented “next to” or “left of” the other structures or portions. Like numbers refer to like elements throughout.

Unless the absence of one or more elements is specifically recited, the terms “comprising”, including”, and “having” as used herein should be interpreted as open-ended terms that do not preclude the presence of one or more elements.

As used herein a “ceramic based material” or the term “ceramic based” includes a material that consists primarily of a ceramic material, such as an inorganic, non-metallic material made from compounds of a metal or metalloid and a non-metal (e.g., aluminum nitride (AlN), aluminum oxide (Al₂O₃), beryllium oxide, silicon carbide (SiC). A “non-ceramic based material” consists primarily a metallic material, a primarily organic (e.g., polymeric) material, and/or a primarily synthetic or semi-synthetic organic solid that can be dispensed or molded (e.g., plastic). Light emitter devices, packages, or components described herein can comprise surface mount design (SMD) ceramic based devices or packages (e.g., LED chips disposed over a ceramic submount) SMD molded plastic based devices or packages, and/or non-SMD type packages.

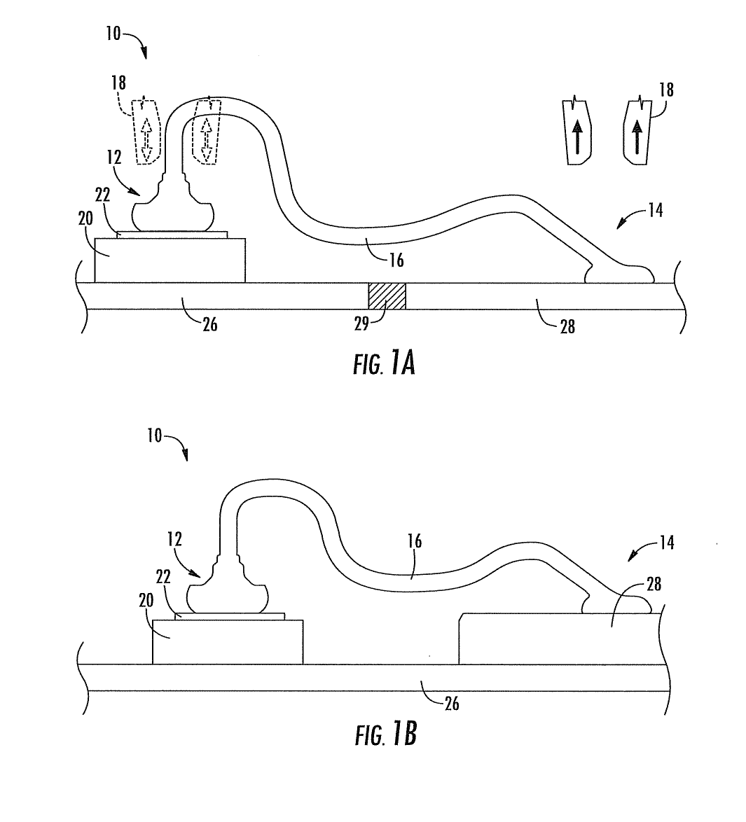

Referring to FIGS. 1A to 8, wire bonds and light emitting devices and related methods for forming wire bonds, particularly for use with light emitting diode (LED) devices, are described. In general, wire bonding provides an electrical interconnection between two or more electrical devices, such as between an LED chip and an electrically conductive substrate associated with and/or within light emitter device, package, or component. For example, LED chips can be wire bonded to portions of electrical substrates including portions of an electrically conductive pad, a PCB, a MCPCB, a flexible circuit, an FR-4 laminate, an electrical contact, a metallic trace, combinations thereof, and/or any other electrical component associated with and/or disposed within a light emitter device, package, component, or fixture. Electrical components such as electrically conductive substrates can supply electrical current and/or supply the electrical connection to the one or more LED chips.

Wire bonding can comprise provision of a thin wire which can electrically connect to a portion of the LED chip and a portion of the electrically conductive substrate (and/or interconnect two or more LED chips or two electrically conductive traces) upon application of heat, pressure, and/or ultrasonic energy to provide an electrical bonding. Wire bonding can, for example, comprise provision of wires such as wires less than 1 mil thick, approximately 1 mil to 1.25 mil, or greater than 1.25 mil. Thinner wires may be more advantageous by allowing for better flexure and/or elongation and thicker wires can withstand more stress. Thus, depending upon the application and/or desired results, thicker or thinner wires can be used where appropriate. In one aspect, wire bonding can comprise a solid phase welding process whereby two metallic surfaces (e.g., a bond pad of an LED chip and the thin wire) are brought into intimate contact and welded together.

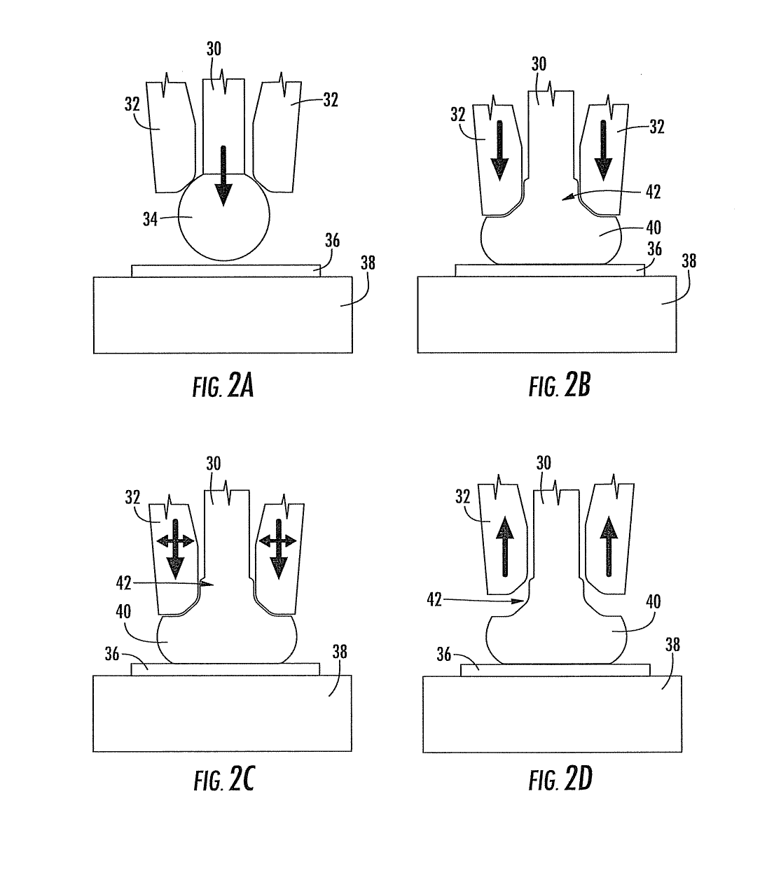

FIGS. 1A and 1B illustrate novel shaped wire bonds provided via novel wire bond shaping processes which can advantageously compensate for and/or resist CTE mismatch between different materials within a light emitter device. In one aspect, a wire bond (or bond wire) is generally designated 10. Wire bond can comprise a first end generally designated 12 and a second, opposing end generally designated 14. A shaped wire portion 16 can be disposed between first and second ends 12 and 14. First and second ends 12 and 14 can be fixedly attached such as via atomic diffusion into portions of electrically conductive components, surfaces, and/or substrates. One or more of the ends, such as first end 12 for example, can comprise a ball bond and neck portion (e.g., 40 and 42, FIGS. 2B to 2E) which can form during a ball bonding process. Second end 14 can comprise a stitched end of essentially melted and smeared metal which also forms during the ball bonding process, when capillary 18 terminates the ball bonding process. A portion of capillary 18 is shown and is for illustration purposes shown in broken lines. In one aspect, first and second ends 12 and 14 can, but do not have to, become disposed over and/or affixed to materials having different CTEs and/or be used within a package comprised of multiple materials having multiple CTEs. For example, first end 12 can be disposed over a portion of a light emitter chip, such as a LED chip 20. In one aspect, first end 12 can be disposed over a contact portion or bond pad 22 of LED chip 20. Second end 14 of wire bond 10 can be disposed over a first electrically conductive surface or substrate 28. LED chip 20 and conductive substrate 28 can electrically communicate via wire portion 16 of wire bond 10.

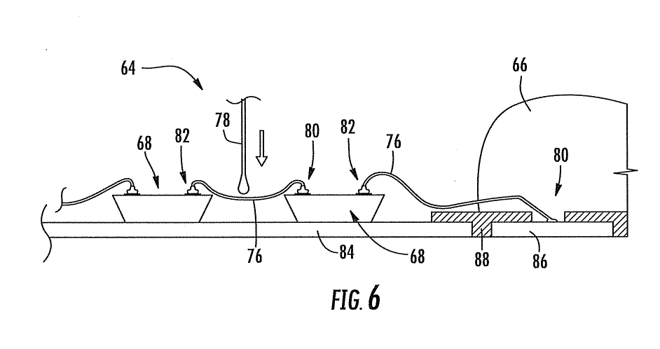

As FIG. 1A illustrates, a capillary 18 of a wire bonding tool can move laterally and/or downwardly from a first position (e.g., illustrated in broken lines over bond pad 22 of LED chip 20) to a second position (e.g., disposed over a portion of an electrically conductive substrate 28) to form wire bond 10 therebetween. Thus, shaping or manipulation of wire bond 10 can be performed during wire bond formation by changing parameters and/or loop settings on wire bonding machine to form a downward, negative loop in wire portion 16. In further embodiments, shaping or manipulation of wire bond 10 can be performed after formation of wire bond 10 (but prior to encapsulation of wire bond 10 within silicone) using a tool 78 such as illustrated in FIG. 6.

LED chip 10 can be disposed over a portion of an adjacent, second substrate 26 that can be electrically conductive or non-electrically conductive. Each of conductive substrate 28 and second substrate 26 can comprise any material. Further, conductive substrate 28 and second substrate 26 can comprise the same and/or different materials. Where second substrate 26 is electrically conductive, an insulating portion of material 29 can be disposed between electrically conductive substrate 28 and second substrate 26. In general, electrically conductive substrate 28 can comprise any electrically conductive material. In one aspect, electrically conductive substrate 28 can comprise a metallic trace, a lead frame, or portions of a PCB, a MCPCB, a FR-4 laminate, a flexible circuit, and/or combinations thereof. Second, adjacent substrate 26 can comprise a metallic trace or mounting pad, a plastic molded portion of a light emitter package, a ceramic based submount, or any of the same materials as electrically conductive substrate 28 (e.g., a metallic trace, lead frame, portions of a PCB, MCPCB, FR-4 laminate, flexible circuit, or combinations thereof). Electrically conductive substrate 28, LED chip 20, bond pad 22, and second substrate 26 can each comprise a plurality of different materials and can therefore each comprise a plurality of different CTEs associated with each material. The resultant mismatch in CTEs could result in stress to and movement of wire bond 10 as different portions expand/contract differently when subjected to elevated operation temperatures. Notably however, wire portion 16 of wire bond 10 can elongate and/or move upwards/downwards during thermal cycling or movement to alleviate any stresses caused by CTE mismatch, movement, and/or vibration during operation within an LED device or package. Wire bonds 10 disclosed herein can electrically connect any types (e.g., the same and/or different) of electrical components, such as two LED chips, two electrical traces, two electrical contacts, etc.

In one aspect, bond pad 22 can comprise a first material, such as Au, Ag, Cu, Ti, Pt, and/or combinations thereof. In one aspect, bond pad can have a CTE of approximately 14 ppm/° C. (e.g., a CTE of Au or Au alloy). Conductive substrate 28 and second substrate 26 can comprise any portions of a light emitter device or package and/or any materials (the same or different) which may be used within a light emitter device or package. Substrates 28 and 26 and/or any portion of substrates 28 and 26 can comprise a ceramic substrate (e.g., AlN, Al₂O₃, ZrO₂) having a CTE of approximately 7 to 8 ppm/° C. such as 8.2 ppm/° C., an FR-4 laminate or a PCB having a CTE of approximately 14 ppm/° C. to 30 ppm/° C. and/or a metallic trace, mounting pad, or leadframe comprised of metals having a CTE ranging from approximately 14 ppm/° C. to 17 ppm/° C. The CTE of substrates 28 and/or 26 can be different from each other, and different from the CTE of bond pad 22.

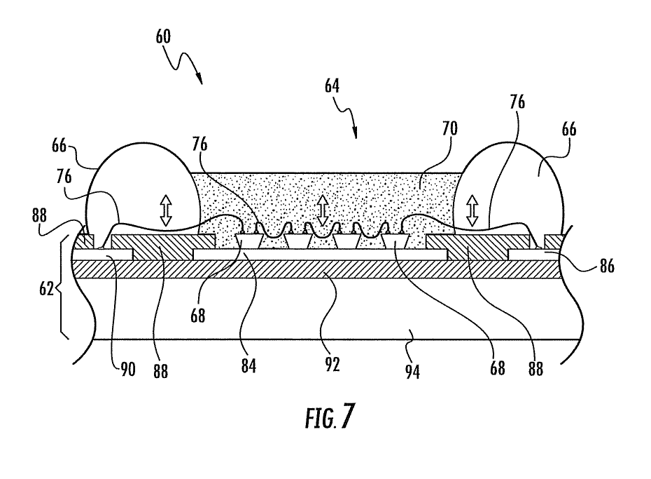

As described below, portions of wire portion 16 can be surrounded by a silicone epoxy, encapsulant, and/or a silicone dam material (e.g., FIGS. 6 and 7) after formation. Such epoxies and silicone materials can have a relatively high CTE that can be different and/or higher than the CTEs of bond pad 22, conductive substrate 28, and/or second, adjacent substrate 26. A relatively high CTE material can be approximately 40 ppm/° C. or more. In one aspect, the CTE associated with silicone encapsulant and/or dam materials (e.g., FIGS. 6 and 7) can comprise approximately 40 to 50 ppm/° C., approximately 50 to 55 ppm/° C., approximately 55 to 150 ppm/° C., approximately 150 to 300 ppm/° C., approximately 275 ppm/° C., and/or more than 300 ppm/° C. Thus, as the light emitter device heats up, the LED chip 38, substrate 28, second, adjacent substrate 26, and/or silicone or encapsulant (e.g., filling material 70, FIG. 6) can expand at different rates and move, stress, or strain portions of wire portion 16. Conventional wires tend to break under such stress; however, novel shaped wire portion 16 disclosed herein can advantageously be elongated by being bent downwards and/or at least partially concave in shape.

As FIGS. 1A and 1B further illustrate, wire portion 16 can be shaped via moving capillary 18 during wire bond formation and/or pushing downwardly upon wire portion 16 after formation of wire bond 10. Notably, high CTE materials such as silicone (e.g., filling material 70 FIG. 7) can push upwardly on wire portion 16 during operation of the light emitter device as portions of conductive substrate 28 pull away from LED chip 20, and wire portion 16 and can resist breakage. By shaping or configuring a portion of wire bond 10 to be at least partially concave and/or “negatively” kinked with respect to substrates 26, 28 and/or LED chip 20. Between its opposing ends, wire bond 10 therefore can have a length that can be referred to as a connecting portion, and at least a portion of the connecting portion can comprise an additional length that can relieve stresses caused by CTE mismatch between portions of LED chip 20, conductive substrate 28, second substrate 26, and/or silicone (e.g., filling material 70 and/or retention material 66 in FIGS. 6 and 7). As FIGS. 1A and 1B illustrate, portions of wire bond 10 can be at least partially concave and/or convex. For example, wire bond 10 can be at least partially convex proximate first and second ends 12 and 14, respectively, and wire bond 10 can be least partially concave proximate a middle of wire portion 16. Wire bonds 10 having multiple additional concave and convex portions are contemplated. Notably and for example, wire bonds 10 comprising shaped wire portions 16 disposed between first and second ends 12 and 14, respectively, can be used in devices incorporating different materials with CTE mismatch(es) of between approximately 1 and 10 ppm/° C. at 125° C. (e.g., such as a difference in growth of ceramic based substrate and electrically conductive substrate of between approximately 1 and 50 μm).

As FIG. 1B illustrates, portions of LED chip 10 and conductive substrate 28 can be disposed over portions of second substrate 26. In this embodiment, conductive substrate 28 can be non-planar and/or disposed above second substrate 26. In one aspect, second substrate 26 can comprise a ceramic based material and conductive substrate 28 can comprise an electrically conductive material such as a metallic trace, leadframe, metallic layer, a portion of a PCB, MCPCB, FR-4 laminate, flexible circuit, and/or combinations thereof. Substrate 26 and 28 can comprise the same and/or different materials. Substrates 26 and 28 can comprise rigid materials, flexible materials, and/or combinations thereof. Where different materials are used, the mismatch in CTE can occur and can put stresses and/or strains upon wire portion 16. Alternatively, where substrate 28 comprises a flexible circuit, motion of portions of the flexible circuit cause the stresses and/or strains in addition to and/or separate and apart from a temperature change. Wire portion 16 can become strained or stressed due to temperature changes, motion between flexible parts within a lighting device, and/or due to vibration of device or package components during operation. In this aspect, a portion of the downwardly shaped wire bond or wire portion 16 can advantageously be substantially concave thereby allowing wire portion 16 to bend, move, and/or flex upwardly and alleviate stresses and/or strains that may result during operation.

Notably, by positioning a portion of wire portion 16 at least partially concave and non-planar with at least one loop portion that extends at least generally downwardly, such as toward a substrate, with respect to and/or on a lower plane than either one or both ends 12 and 14, wire portion 16 can comprise an additional length available to relieve stress and can laterally elongate as needed to accommodate for CTE mismatch or movement within a light emitter device, package, or component. In one aspect, a high CTE material such as silicone encapsulant or dam material can push wire portion 16 vertically upwards causing it to laterally elongate. The shape of wire portion 16 can comprise a downward loop or a negative kink which can be provided by the downward and/or lateral capillary 18 movements (e.g., reducing loop height, wire bond profile, and/or parameters of wire bonding machine) or by using a tool to push downwardly and apply a kink in the wire portion 16 after formation of wire portion 16 and wire bonded ends. The portion of low laying wire portion 16 can be disposed close to the underlying substrate, in one aspect to minimize the amount of high CTE material (e.g., filling material, silicone, or encapsulant) disposed under the wire portion 16 which will increase the amount of compensation required. However, minimization of an amount of high CTE material below wire portion 16 is not required and may not be desired in certain aspects. The expanding silicone or high CTE material (e.g., approximately 40 ppm/° C. or more) under wire portion 16 helps provide the length needed to prevent breakage at the ends of wire bond 10. Application of a negative kink can advantageously increase the amount of wire portion 16 available for thermal compensation and can avoid a short-tight wire between fixed, which could lead to breakage in conventional components.

Notably, the additional length of wire portion 16 between ends of wire bond 10 can resist and/or improve resistance to stresses, strains, and breakage due to CTE mismatch, partly by allowing wire portion 16 to move upwards and/or downwards (see, e.g., FIG. 7). In other aspects, wire bonds and wire bonding processes described herein can reduce pivoting at respective ends of wire bonds. Wire bonds and wire bonding described herein can advantageously move and/or elongate in any direction as allowed by the wire length in order to accommodate for CTE mismatches, accommodate for movement between portions of a flexible circuit, and/or accommodate for any vibrations that may occur during operation of the light emitter device or package. Notably, wire bonds and/or wire portions 16 of wire bonds 10 can move upwards or downwards and/or even laterally (sideways) left or right. This is particularly advantageous during thermal cycling to accommodate for any mismatch(es) in CTEs of different materials which expand and/or contract differently during elevated and/or cooler or cold operating temperatures. Wire bonds disclosed herein can comprise any electrically conductive material such as gold (Au); Au alloys; aluminum (Al); Al alloys; copper (Cu); Cu alloys; silver (Ag); Ag alloys; and/or combinations thereof.

FIGS. 2A to 2D schematically illustrate a ball bonding wire bond and wire bonding process, similar to what produce the result shown in FIG. 2E. Ball bonding is shown for purposes of simplification to illustrations herein, and it should be noted that wire bonds and wire bond shaping can be used with wedge bonding and/or wedge bonds as a wedge bond is shown in FIG. 2F. Any other suitable bond or bonding technique could also be used in accordance with the disclosure herein. According to FIG. 2A, a wire 30 can be fed through a capillary 32 portion of a wire bonding tool. Capillary 32 can comprise a portion of an automatic and/or manual wire bonding tool, such as any tool manufactured by Kulicke & Soffa Corporation, (i.e., K&S Corp.) having headquarters in Fort Washington, Pa. or ASM Pacific Technology, Ltd., having headquarters in Hong Kong. A free air ball (FAB) 34 can be disposed at the end of wire 30, and can be formed, for example, via heating up the bottom tip of wire 30 with an electrostatic discharge. FAB 34 can be moved towards and contact an underlying electrically conductive substrate. In this embodiment, FAB 34 can be disposed over and move towards a bond pad 36 of an LED chip 38. LED chip 38 can comprise a vertically structured chip (e.g., more than one bond pad or electrical contact, such as an anode and a cathode bond pad on the top surface of the LED chip) or a horizontally structured chip (e.g., contacts such as anode and cathode bond pads on opposing surfaces of the LED chip).

As FIG. 2B illustrates, capillary 32 can move down and cause FAB 34 to impact bond pad 36, causing a ball bond 40 and neck portion generally designated 42 to form. As FIG. 2C illustrates ultrasonic energy, heat, and/or pressure (e.g., applied downwards and/or laterally) can be applied to ball bond 40 to allow portions of ball bond 40 to diffuse into and adhere to portions of bond pad 36. As FIG. 2D illustrates, capillary 32 can move upwards and continue to feed wire 30.

FIGS. 2E and 2F are micrographs of the two basic forms of wire bonds, the ends of which can be disposed between shaped wire portions as described in FIG. 1A. FIG. 2E is an example of ball bonding whereby a capillary tool applies heat, pressure, and/or ultrasonic power (e.g., scrubbing power) to form a ball bond over another electrically conductive surface (e.g., a wire bond, electrical trace, or circuit component). As FIG. 2E illustrates, ball bond can comprise a neck or neck portion which can form just above the ball bond. The neck portion can comprise a heat affected zone (HAZ) of metal above which a thin wire portion can extend. The HAZ of neck portions can be susceptible to breakage when wire portion flexes, is strained, or is under stress during operation of a light emitter package.

FIG. 2F is an example of a wedge bond. Although ball bonding processes are shown herein, wedge bonds and related processes could also be used. Wedge bonds can be formed via a wedge bonding tool which can melt and/or smear portions of a wire over a portion of an electrically conductive surface or substrate. The wedge bonding tool can use pressure and/or heat to cause wedge bond to adhere and diffuse into portions of an LED chip bond pad or electrical element/component of a light emitter package. Wedge bonding can leave a “pig tail” portion disposed over a portion of the surface adjacent the main body of the wedge bond. A wire portion can extend from the wedge bond and electrically connect two components such as two LED chips, an LED chip and a metallic trace, or two metallic traces. In both cases illustrated in FIGS. 2E and 2F, metallic atoms of the wire bond, proximate either the ball bond or the wedge bond can diffuse into the respective underlying electrically conductive substrates and become firmly bonded thereto.

Of note, one of the fixed ends (e.g., second stitched fixed end 14, FIG. 1) can be similar to a wedge bond as the wire can be stitched off without a ball. In addition to ball bonding and wedge bonding, other methods and/or types of fixed ends derived from other methods of wire bonding are contemplated herein. For example, other methods or techniques may just use a stitch, may apply stitching on a bump bond, and/or may putting a bump bond on top of a stitch as security bond as known in the art. All wire bonds and wire bonding methods are contemplated herein, and can at least partially be used to form fixed ends and/or other portions of a wire bond prior and/or during formation of a shaped wire bond as disclosed herein.

In general, FIGS. 2A to 2D can illustrate a method of forming a wire bond in a light emitter device or package to accommodate stresses and/or strains that may arise in the emitter device during thermal cycling at elevated operation temperatures. The method can comprise positioning at least one light emitter chip (e.g., an LED chip) over a substrate. The substrate can have a first CTE. The method can further include attaching a wire bond to the chip at a first end of the wire bond and attaching a second end of the wire bond to a material having a second CTE that is different from the first CTE. A loop can be formed in the wire bond to allow movement of at least a portion of the wire bond during heating of the light emitter device. The loop can comprise convex portions, concave portions, and/or multiple combinations thereof.

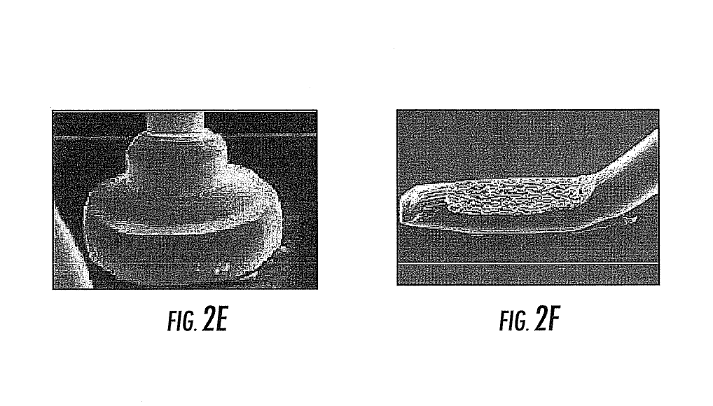

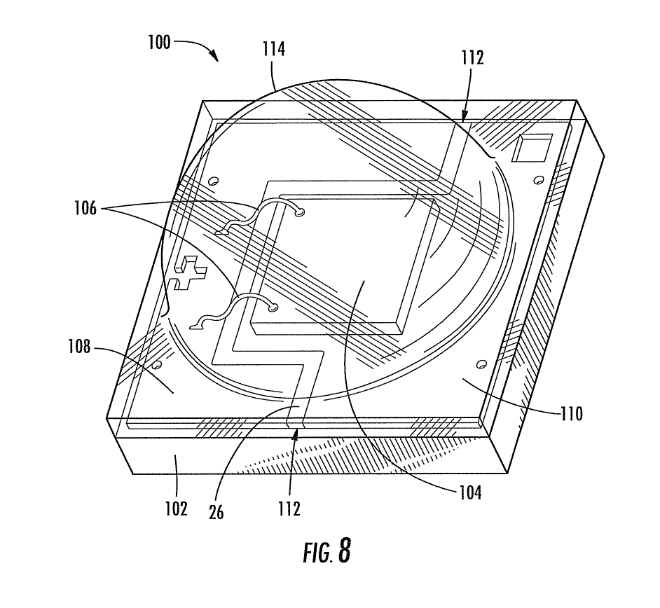

FIGS. 3 through 8 are examples of light emitter devices, packages, or components which incorporate novel shaped wire bonds, wires, and/or wire bonding shaping processes described herein to compensate for thermal expansion. Referring now to FIGS. 3 to 7, views of a first light emitter package or device, generally designated 60 are shown. For simplification of illustrations herein, two different light emitter devices 60 and 100 (FIG. 8) components, or packages are disclosed. However, wire bonds and wire bonding techniques described herein can be used with or within any light emitter device, package, and/or component, including packages or components having silicone encapsulated wires or wire bonds.

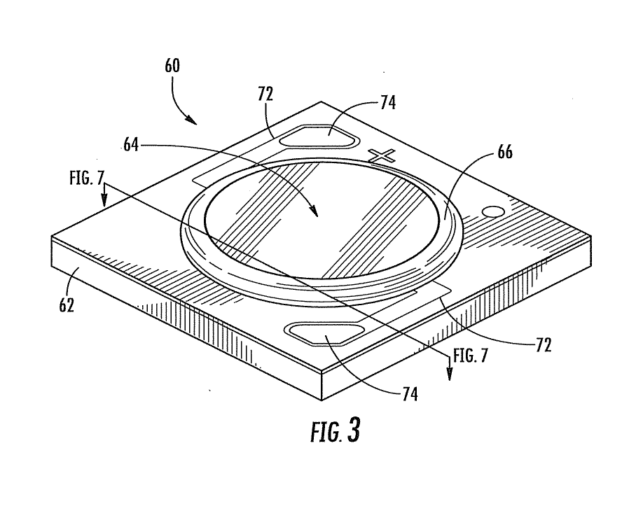

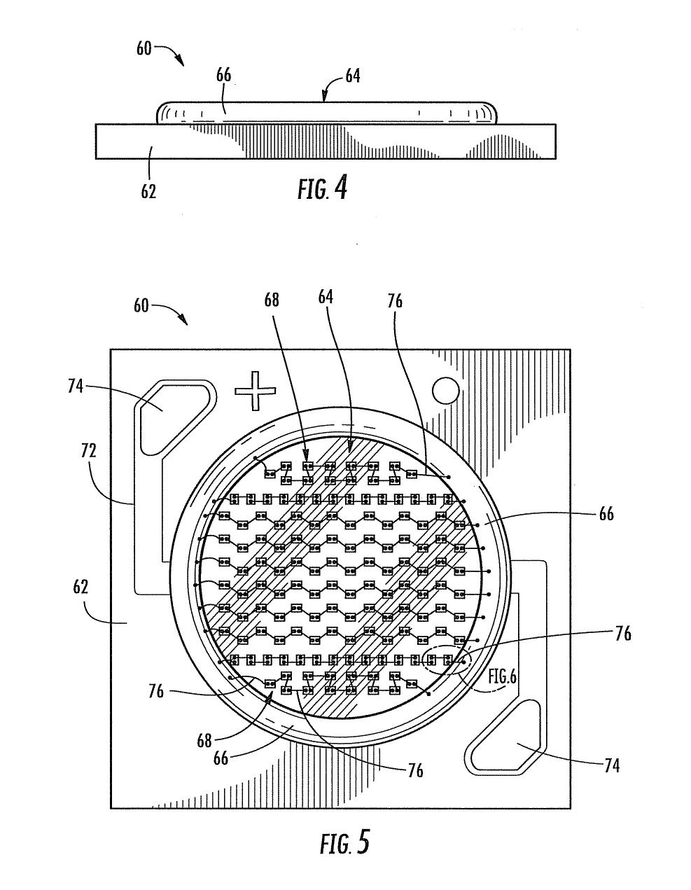

Referring to FIGS. 3 through 7, light emitter device 60 can comprise a submount 62 for supporting one or more LED chips (66, FIG. 5). In one aspect, an emission area generally designated 64 can be disposed over a portion of submount 62. A retention material 66 can be disposed about a portion of emission are 64. Emission area 64 can be centrally or non-centrally disposed with respect to light emitter device 60. Emission area 64 can comprise any shape including a circular shape, a non-circular shape, a symmetrical shape, and/or an asymmetrical shape. In some aspects, more than one emission area 64 is contemplated. Retention material 66 can comprise rounded or non-rounded outermost edges as shown in FIG. 4. In one aspect, retention material 66 can comprise any suitable material that is dispensable, for example, any transparent, opaque, or colored silicone or silicone encapsulant material, with or without fillers.

Submount 62 can comprise any suitable mounting submount or substrate, for example, a PCB, a MCPCB, an external circuit, a flexible circuit, a FR-4 laminate, or any other suitable submount or substrate over which light emitters such as LED chips can mount and/or attach. Portions of submount 62 can expand or contract differently during elevated operating temperatures due to a mismatch in CTE. Portions of submount 62 can also move or vibrate causing stress to wire bond connectors between LED chips and/or portions of submount. Notably, wire bond connectors used within device 60 can comprise a concave shape and/or negative loop or kink disposed toward the underlying substrate and that allows for elongation and stress relief to wire bonds during operation of device 60.

As FIG. 5 illustrates, emission area 64 can comprise a plurality of LED chips generally designated 68 disposed within and/or below a filling material 70 as illustrated in FIG. 7. LED chips 68 can comprise any suitable size, shape, material, type, structure, build, and can comprise a carrier or growth substrate. Filling material 70 can comprise a silicone encapsulant (e.g., a methyl or phenyl silicone) having a predetermined, or selective, amount of phosphors and/or lumiphors in an amount suitable for any desired light emission, for example, suitable for white light conversion. Filling material 70 can interact with light emitted from the plurality of LED chips 68 such that a perceived white light, or any suitable and/or desirable color of light, can be observed from emission area 64. Upon placement of retention material 14, filling material 70 can be selectively filled to any suitable level within the space disposed between one or more inner walls of retention material 66.

Still referring to FIGS. 3 to 7, light emitter device 60 can optionally comprise at least visible trace 72 disposed at least partially outside of retention material 60 over substrate 62. Light emitter device 60 can also comprise one or more optional electrical attachment surfaces 74. In one aspect, attachment surfaces 74 comprise electrical contacts such as solder contacts. Attachment surfaces 74 can be any suitable configuration, size, shape and/or location and can comprise positive and negative electrode terminals through which an electrical current or signal can pass when connected to an external power source. One or more electrically conductive wires (not shown) can be attached and electrically connected to attachment surfaces 74 when welded, soldered, or any other suitable attachment method known. Electrical current or signal can pass into light emitter device 60 from the external wires (not shown) electrically connected to the attachment surfaces 74 and into emission area 64 to facilitate light output. Attachment surfaces 74 can electrically communicate with emission area 64 which comprises one or more LED chips 68. Attachment surfaces 74 can electrically communicate with first and second conductive traces 86 and 90 (FIG. 7) and therefore LED chips 68 which may be electrically connected using electrical connectors. Electrical connectors can comprise wire bonds 76 or other suitable members for electrically connecting LED chips 68 to first and second conductive traces 86 and 90 (FIG. 7). As an alternative to attachment surfaces 74, drive circuitry which is integrally disposed within a portion of device 60 can also be used.

As FIG. 5 illustrates, LED chips 68 can be arranged in more than one pattern, string, or segment. Each LED chip 68 within a string can be electrically connected in series, and each string can be electrically connected in parallel to other adjacent strings. Any combination of patterns, serially and/or parallel LED chip 68 arrangements are contemplated herein. In FIG. 5, wire bonds 76 can be substantially straight and/or laterally curved when viewed from above. Laterally curved wire bonds (e.g., visible on the left hand side of outermost LED chips 68 in FIG. 5) can advantageously expand in length to accommodate mismatches in CTE for various materials within submount 62 during an increase in operating temperature and/or movement or vibration to portions of device 60 during operation. Curved wire bonds 76 can also reduce pivoting between and/or proximate each fixed end of the wire bond.

FIG. 6 is a detail view of LED chips 68 and retention material 66 in FIG. 5. As FIG. 6 illustrates, each wire bond 76 can comprise a first end 80 and a second end 82 (e.g., ball bonds) fixedly disposed between adjacent LED chips 68 and/or between portions LED chips 68 and electrical traces. Notably, portions of wire bonds 76 can be shaped such that they are substantially concave and/or negatively looped or kinked with respect to the underlying substrate and/or LED chips 68 to allow for movement, elongation, stretching, and/or stress/strain relief during operation of device 60. In one aspect, wire bonds 76 can extend towards the surface upon which LED chips 68 are mounted such that portions of the wire bonds 76 are approximately equal with and/or below an upper surface of LED chips 76. That is, the portion between the ends of the wire bond can be referred to as a connecting or middle portion and at least a portion of the connecting portion can be disposed and/or extend below a plane of a surface of the LED chip, such as below a plane of an upper surface of the LED chip 76.

Wire bond shaping can be accomplished via positioning of the wire bonding tool during formation of wire bond 76 (e.g., by adjusting height, loop height, and/or machine parameters of capillary). In other aspects, wire bond shaping can be accomplished by using a tool, such as for example as by using tool 78. Tool 78 can be used after formation of wire bonds 76 to push downwardly and/or form a negative kink in a portion of wire bond 76. Tool 78 can also position wire bond close to underlying portions of submount 62, such as close to an electrically conductive pad 84 (e.g., a mounting pad) over which LED chips 68 are disposed. Notably, wire bonds 76 can comprise shapes that can see minimal CTE stresses. As FIG. 6 illustrates, wire bonds 76 disposed between adjacent LED chips 68 can be shaped such that a portion of wire bond 76 proximate the middle of the wire bond (or approximately half of the distance between the adjacent LED chips 68) can extend below an upper surface of each LED chip 68 to which it is connected.

Still referring to FIG. 6, portions of wire bonds 76 can be disposed within portions of retention material 66. Retention material 66 can also comprise a high CTE silicone material that can push up on portions of wire bonds 76 during operation thereby allowing portions of wire bond 76 to vertically and/or laterally elongate to compensate for CTE mismatch between portions of retention material 66 and submount 62. Wire bonds can electrically connect LED chips 68 to a first electrical trace 86 and a second electrical trace (90, FIG. 7). Solder mask material 88 can be disposed between portions of first and second electrical traces 86 and 90 (FIG. 7) and conductive pad 84 for physical and/or electrical separation thereof.

FIG. 7 illustrates a portion of a cross-section of FIG. 1 wherein a filling material 70 is disposed within emission area 64. As the double ended arrows in FIG. 7 illustrate, portions of wire bonds 76 can move upwards during elevated temperatures and downwards during cooler temperatures, such as, for example, during thermal cycling which can occur during operation of device 60. For illustration purposes, four LED chips 68 are illustrated and electrically connected in series in FIG. 7. However, each string, or pattern of LED chips 68 can comprise any suitable number of LED chips. FIG. 7 further illustrates a cross-section of submount 62 over which LED chips 68 can be mounted or otherwise arranged. Submount 62 can comprise many different materials or layers, for example, conductive pad 84, first and second conductive traces 86 and 90, respectively, and solder mask 88 at least partially disposed between conductive pad 84 and each of first and second conductive traces 86 and/or 90. Submount 62 can further comprise a dielectric layer 92, and a core layer 94. For illustration purposes, submount 62 can comprise a MCPCB, for example, those available and manufactured by The Bergquist Company of Chanhassan, Minn. Any suitable submount 62 can be used, however. Core layer 94 can comprise a conductive metal layer, for example Cu or aluminum (Al). Dielectric layer 92 can comprise an electrically insulating but thermally conductive material to assist with heat dissipation through submount 12.

FIG. 7 further illustrates filling material 70 disposed over the one or more LED chips 68. Filling material 70 can be selectively filled to any suitable level higher, lower, or equal to the height of retention material 66. Wire bonds 76 of outermost LED chips 68 can be at least partially disposed within a portion of retention material 66. Notably, wire bonds 76 disposed between adjacent LED chips 68 can be shaped to be substantially concave. As filling material 70 can comprise a high CTE material, it can push up on portions of wire bonds 76 during elevated operating temperatures. Wire bonds 76, because of the additional length or “slack” between LED chips 68 can resist breakages due to stresses and/or strains that occur during operation of light emitter device 60. Retention material 66 can also comprise a high CTE material which can push up on portions of wire bonds 76 disposed between outermost LED chips 68 and electrical traces. Any amount of CTE mismatch can be minimized by the additional length of wire bonds 76 which can be pushed downward towards the underlying portion of submount 62.

FIG. 8 illustrates another type of light emitter device generally designated 100. Light emitter device 100 can comprise a substrate or submount 102 and at least one LED chip 104 disposed over submount 102. Submount 102 can comprise any suitable material, for example, an electrical insulating (e.g. non-electrically conductive) material with a low thermal resistance and/or high thermal conductivity. In one aspect, submount 12 can comprise a non-metallic material, such as a ceramic or ceramic based material. For example, submount 102 can comprise Al₂O₃ and derivatives thereof, AlN and derivatives thereof, SiC and derivatives thereof, ZrO₂ and derivatives thereof, TiO₂ and derivatives thereof, combinations thereof, and/or any other ceramic based or ceramic containing material. Submount 102 can comprise any suitable dimension that can vary depending upon, for example, chip size and/or number of LED chips. In some aspects, at least one side of submount 102 can comprise approximately 1 mm or more, approximately 2 mm or more, approximately 3 mm or more, approximately 3.5 mm or more, approximately 5 mm or more, approximately 7 mm or more, approximately 9 mm or more, or more than 10 mm. In some aspects, substrate 102 can comprise a square measuring approximate 3.5 mm×3.5 mm or more.

One or more areas or portions of electrically conductive material can be disposed over one or more portions of submount 102. For example, a first electrically conductive trace 108 and a second electrically conductive trace 110 can be provided and disposed over submount 102. Device 100 can be reversible with respect to electrical polarity, that is, wire bonds 106 can electrically connect to an anode and/or a cathode (e.g., first and second traces 108 and 110). First and second traces 108 and 110, respectively, can be physically and/or electrically separated by a gap generally designated 112. In one aspect LED chip 104 can be entirely disposed over a portion of second electrical trace 110 without traversing and/or being disposed over any portion of gap 112. First and second traces 108 and 110, respectively, can be provided over submount 102 via chemical deposition, physical deposition, chemical vapor deposition, plasma deposition, electrolysis, electroplating and/or electroless plating techniques.

Notably, LED chip 104 can be wire bonded to portions of first electrical trace 108 via wire bonds 106. Wire bonds 106 can be shaped such that at least a portion of each wire bond is concave and/or negatively looped or kinked. This shaping or configuration provides additional length or slack within the wire to address CTE mismatch and/or vibrational shifting that may occur during operation of device 100. Portions of wire bonds 106 can be disposed within and/or below a lens 114. Lens 114 can comprise glass or a molded silicone lens. Where molded, portions of silicone lens can advantageously push upwardly on wire bonds 106 to elongate or extend the bonds. In some aspects, silicone can move upwardly approximately 40 ppm/° C. to more than approximately 300 ppm/° C. In some aspects, silicone may be greater than approximately 200 ppm/° C. (unless heavily filled with phosphor or a diffuser). The wire bond shaping and elongated length can reduce any potential damage which may be inflicted to the wire bond 106 by stress or strain.

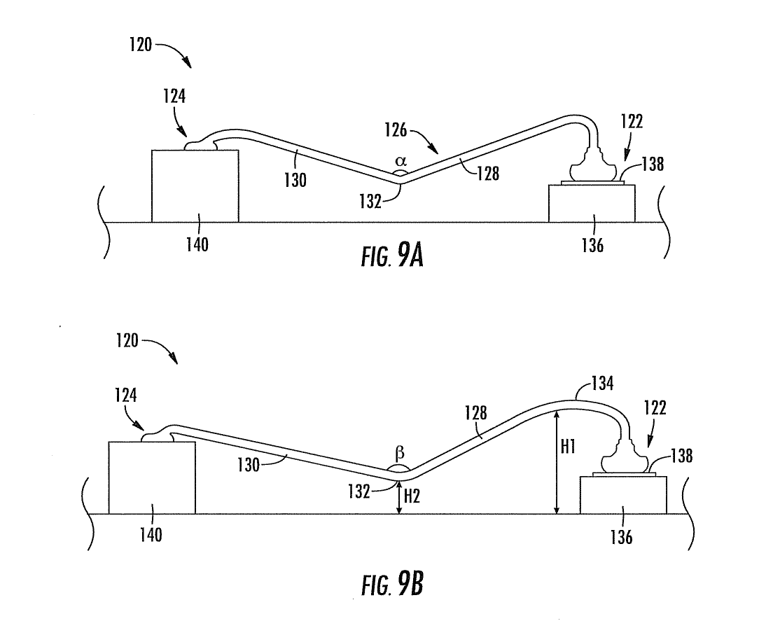

FIGS. 9A and 9B schematically illustrate angles and/or dimensions associated with novel wire bonds and wire bonding processes disclosed herein. In FIGS. 9A and 9B, a novel wire bond generally designated 120 is illustrated. Wire bond 120 can be disposed within any light emitter device and/or package or can be used in any environment having one or more LED chips. Wire bond 120 can comprise a first end generally designated 122, a second end generally designated 124, and a connecting or middle portion. Connecting portion can comprise a wire portion generally designated 126 disposed between first and second ends that can comprise a first portion 128 and a second portion 130. Each of first and second portions 128 and 130 can incline at an angle and extend downwardly converging towards a common point, such as a lowest point 132 disposed between first and second portions 128 and 130 such that lowest point 132 forms and angle between first portion 128 and second portion 130. Lowest point 132 can be disposed proximate a center of connecting portion, or wire portion 126 of wire bond 120.

In FIGS. 9A and 9B, first end 122 can be disposed over and fixedly attach to a bond pad 138 of an LED chip 136. Second end 124 of wire bond 120 can fixedly attach to a portion of substrate 140. Substrate 140 can comprise any material and/or materials such as a portion of a FR-4 laminate (e.g., and any dielectric material including FR-4), PCB, MCPCB, a metallic trace, a flexible circuit, etc. Notably, wire bond 120 can have a negative kink or loop extending towards a lowest point 132 between first and second ends 122 and 124, such that wire portion 126 can move upwardly and/or downwardly during thermal cycling as necessary within a light emitter device or package. Wire portion 126 can advantageously include an extra length for alleviating any potential stresses or strains that may occur due to CTE mismatch, vibration, and/or any movement in general that may occur in light emitter devices or packages.

In FIG. 9A, an angle α can be disposed proximate lowest point 132 in loop or “dip” portion of the wire bond. In one aspect, lowest portion 132 can be disposed proximate the middle of the wire portion 126 of wire bond 120, or between the fixed ends. Angle α can be sharp (FIG. 9A) or smooth (FIG. 9B). In one aspect, angle α can range from approximately 1° to less than 180°, such as, for example sub ranges including between approximately 90° to 120°, approximately 120° to 140°, approximately 140° to 150°, or approximately 150° to 179°.

In FIG. 9B, lowest point 132 can also be disposed proximate the middle of the wire portion 126 of wire bond 120, or between the fixed ends. Angle β can be smoother than the sharp angle of FIG. 9A. In one aspect, angle β can range from approximately 1° to less than 180°, such as, for example sub ranges including between approximately 90° to 120°, approximately 120° to 140°, approximately 140° to 150°, or approximately 150° to 179°. A highest point 134 of wire bond 120 can be disposed above a neck portion of wire bond 120 as illustrated in FIG. 9B. Highest point 134 can extend to a height H1 that is approximately 220 to 320 μm above the surface of the substrate. However, height H1 can depend upon thickness of the LED chip that is being wire bonded (e.g., over which neck portion can be located).

Lowest point 132 of wire bond 120 shown in FIG. 9B can extend to a second height H2 above the surface of the underlying substrate. Second height H2 can be approximately 80 to 200 μm above the underlying substrate. In one aspect, second height H2 is lower or less than first height H1 (e.g., lower than neck portion of wire bond 120) and can also be lower than each fixed end of the wire bond.

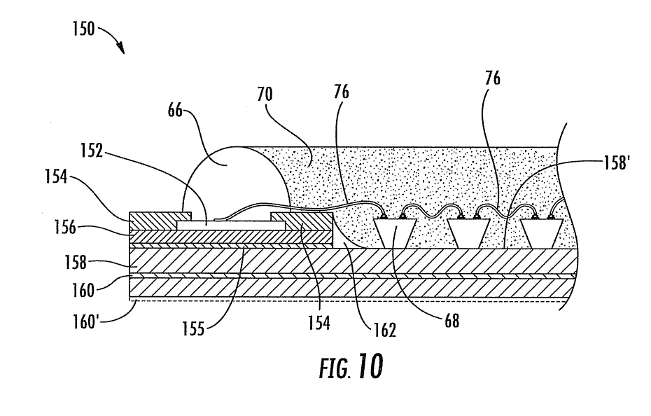

FIG. 10 illustrates a light emitter package or device generally designated 100 which can be similar in form and/or function to device 60, but may comprise different materials within the submount which supports one or more light emitter chips, such as LED chips 68. More than one LED chip 68 can be connected in series (parallel configurations are also contemplated) between first and second electrical traces, such as electrical trace 152. Notably, wire bonds 76 extending between adjacent LED chips 68 can be at least partially concave and/or negatively kinked with respect to an upper surface 158′ of a ceramic layer of the device submount. In addition, wire bonds 76 extending between portions of an outermost LED chip 68 and electrical trace 152 can be at least partially concave and at least partially convex. For example and as FIG. 10 illustrates, wire bond 76 between outermost LED chip 68 and electrical trace 152 can be at least partially concave in a portion of filling material 70 and at least partially convex in a portion of retention material 66 or retention dam. Multiple iterations of concave and convex portions are possible.

As FIG. 10 further illustrates, each LED chip 68 can be disposed over and/or directly mounted to submount including a ceramic layer 158 and one or more non-metallic layers. In one aspect, trace 152 can be adhered directly to a portion of ceramic body 158 in a comparatively simpler process via a lamination technique, such as for example a heat press and/or an overpressure chamber (i.e., autoclave) lamination technique with an adhesive film known to those having skill in the art in the multi-layer printed circuit board industry. In other aspects, a dielectric layer 156 can be disposed between ceramic body 158 and electrical trace 152. More than one dielectric layer can be positioned between ceramic body 158 and any other electrical component or trace as desired. Dielectric layer 156 can comprise any of a variety of material layers known in the art, such as a copper clad laminate (CCL) (e.g., glass-reinforced FR-4, CEM-3, CEM-4, or other related composite materials, such as CS-3965 from Risho). In one particular embodiment, for example, dielectric layer 156 can be a flexible printed circuit board (“flextape” PCB) comprising a polymer-like film having at least one conductive layer within one or more layers of a flexible plastic resin (e.g., polyimide, Kapton from DuPont). In this exemplary configuration, an adhesive layer 155 can comprise a tape-like adhesive provided on the flextape for easy connection to ceramic body 158. It should be recognized, however, that dielectric layer 156 can comprise any material used in multilayer PCBs or flex PCBs, including prepreg materials, reinforced laminates (e.g., glass-reinforced epoxy, materials using carbon fiber), and non-reinforced materials. Each layer can comprise different CTEs, thus, wire bonds 70 can advantageously move upwardly and/or downwardly within portions of filling material 66 and/or retention material 66 as needed to relieve stresses due to CTE mismatch.

As further illustrated in FIG. 10, additional layers and/or components can be integrated into LED device 150 to improve the performance and manufacturability thereof. For example, LED device 150 can further comprise an electrically insulating solder mask 154, which can be disposed on a portion of dielectric layer 156 and at least partially on electrical trace 152. Similarly, a fillet 162 can be provided around a perimeter of a light emitting area defined above the top surface of ceramic body 158, which can be either transparent or reflective (e.g., white). For example, fillet 162 can be made white by incorporating TiO₂ particles therein or by forming fillet 162 of silicone or epoxy materials. Regardless of the specific configuration, fillet 162 can improve reflection of the sidewall portions of LED device 150, thereby compensating in configurations where dielectric layer 156 has a comparatively lesser reflectivity (e.g., where dielectric layer 156 comprises FR-4).

LED device 150 can further comprise a retention material 66 (as previously described in FIGS. 3-8) disposed at least partially about an emission area in which LED chips 68 are positioned, where retention material 66 can be referred to as a dam. After placement of retention material 66, an encapsulant filling material 70 (e.g., a silicone or other relatively high CTE material (e.g., any material having a CTE equal to or greater than approximately 40 ppm/° C.) can be disposed within the recess formed thereby. LED device 150 can also comprise a reflective layer 160 that can, for example and without limitation, be positioned and disposed within a portion of ceramic body 158 as shown in FIG. 10. In another aspect, reflective layer 160′ can as shown in FIG. 10 in broken lines optionally instead only be positioned and disposed on a bottom surface of ceramic body 158 (i.e., a surface opposing the top surface 158′ on which one or more LED chips 68 are disposed). Reflective layers 160 or 160′ can, for example, comprise a metal reflector (e.g., a silver layer), a white thermal compound, or any other material known to limit loss through the bottom surface of ceramic body 158, thereby further improving total reflection of LED device 150. Reflective layers 160 or 160′ can comprise metal or a dielectric material and can for example be two ceramic or other reflective materials bonded together.

Embodiments of the present disclosure shown in the drawings and described above are exemplary of numerous embodiments that can be made within the scope of the appended claims. It is contemplated that the configurations of wire bonds and wire bond shaping for thermal compensation can comprise numerous configurations other than those specifically disclosed herein.

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. A light emitter device comprising:
at least one chip;
a wire bond comprising a first end attached to the chip and an opposite second end;
wherein between the first and second ends, at least a portion of the wire bond comprises a concave shape.

13. The light emitter device according to claim 12, wherein the at least one chip is disposed over a portion of a ceramic based submount.

14. The light emitter device according to claim 12, wherein the device comprises a plurality of materials having a plurality of different coefficients of thermal expansion (CTEs).

15. The light emitter device according to claim 12, wherein the wire bond is encapsulated in a material having a coefficient of thermal expansion (CTE) of approximately 40 ppm/° C. or more.

16. The light emitter device according to claim 12, wherein between the first and second ends, at least a portion of the wire bond comprises a convex shape.

17. The light emitter device according to claim 12, wherein the chip is disposed over a ceramic substrate, and wherein the opposing second end is attached to a metal trace on a printed circuit board (PCB) that is also disposed on the ceramic substrate.

18. A light emitter device comprising:
at least one chip disposed over a substrate;
a wire bond comprising a first end attached to the chip and an opposite second end;
at least a portion of the wire bond forming a loop that extends toward the substrate.

19. The light emitter device according to claim 18, wherein a lowest point of the wire bond is proximate a center point disposed between the first and second ends.

20. The light emitter device according to claim 18, wherein a lowest point of the wire bond is approximately 80 to 200 μm above the substrate.

21. The light emitter device according to claim 18, wherein a highest point of the wire bond is approximately 220 to 320 μm above the substrate.

22. The light emitter device according to claim 18, wherein the chip is disposed over a ceramic substrate, and wherein the opposing second end is attached to a metal trace on a printed circuit board (PCB).

23. The light emitter device according to claim 22, wherein the PCB is also disposed on the ceramic substrate.

24. A light emitter device comprising:
at least one chip disposed over a substrate, the substrate having a first coefficient of thermal expansion (CTE);
a wire bond comprising a first end attached to the chip and an opposite second end attached to a material having a second CTE that is different from the first CTE;
the wire bond forming a loop extending toward the substrate, the loop being sufficient to allow movement of at least a portion of the wire bond.

25. The light emitter device according to claim 24, wherein the device further comprises an encapsulant comprising a third CTE that is different from the first and second CTEs.

26. The light emitter device according to claim 25, wherein the wire bond is encapsulated in the encapsulant.

27. The light emitter device according to claim 25, wherein the third CTE is approximately 40 ppm/° C. or more.

28. The light emitter device according to claim 24, wherein the first CTE is approximately 7 to 8 ppm/° C.

29. The light emitter device according to claim 24, wherein the second CTE is approximately 14 ppm/° C. to 17 ppm/° C.

30. (canceled)

31. (canceled)

32. (canceled)

33. (canceled)

34. (canceled)

35. (canceled)

36. (canceled)

37. (canceled)

38. (canceled)

39. (canceled)

40. (canceled)

41. (canceled)

42. (canceled)

43. (canceled)

44. (canceled)

45. (canceled)

46. (canceled)

47. (canceled)

48. (canceled)

49. (canceled)

50. (canceled)

51. (canceled)

52. (canceled)

53. (canceled)

54. A method of forming a wire bond, comprising:
attaching a wire bond to a light emitter chip; and
extending the wire bond from the light emitter chip in a shape wherein at least a portion of the wire bond comprises a negative kink and/or a concave shape.

55. The method according to claim 54, wherein the wire bond comprises gold.

56. The method according to claim 54, wherein the wire bond has a thickness of approximately 1 mil to 1.25 mil.

57. The method according to claim 54, wherein the wire bond is encapsulated in a material having a coefficient of thermal expansion (CTE) of approximately 40 ppm/° C. or more.

58. The method according to claim 57, wherein the material comprises silicone.

59. The method according to claim 54, wherein a lowest point of a connecting portion of the wire bond is proximate the center between the first and second fixed ends.

60. The method according to claim 54 wherein a lowest point of a connecting portion of the wire bond is approximately 80 to 200 μm above an underlying substrate.

61. The method according to claim 54, wherein a highest point of a connecting portion of the wire bond is approximately 220 to 320 μm above an underlying substrate.

62. The method according to claim 54, wherein at least a portion of a connecting portion of the wire bond extends below a plane of a surface of the light emitter chip.

63. The method according to claim 62, wherein the portion of the connecting portion that extends below the plane of the surface of the light emitter chip is disposed between the light emitter chip and another light emitter chip.

64. The method according to claim 54, wherein the wire bond comprises at least a concave portion and a convex portion.

65. The method according to claim 64, wherein the wire bond comprises at least an additional concave portion and/or convex portion between ends of the wire bond.

66. The method according to claim 54, further comprising attaching the wire bond to a material having a coefficient of thermal expansion (CTE) that is different from a CTE of a substrate to which a light emitter chip is attached.

67. A method of forming a wire bond in a light emitter device, the method comprising:
disposing at least one chip over a substrate, the substrate having a first coefficient of thermal expansion (CTE);
attaching a wire bond to the chip at a first end of the wire bond;
attaching a second end of the wire bond to a material having a second CTE that is different from the first CTE; and
forming a loop in the wire bond to allow movement of at least a portion of the wire bond during heating of the light emitter device.

68. The method of claim 67, comprising adding an encapsulant to the light emitter device that at least partially covers the wire bond, the encapsulant having a third CTE that is different from the first and second CTEs.

69. (canceled)

70. (canceled)
